(19) United States
(12) Patent Application Publication
(10) Pub. No.: US 2002/0122299 A1
(43) Pub. Date: Sep. 5, 2002

(54) Medical work station heat dissipating chassis

(76) Inventors: Clifford Kelly, Windham, NH (US); Scott Newell, Ipswich, MA (US)

Correspondence Address: Siemens Corporation, Intellectual Property Department, 186 Wood Avenue South, Iselin, NJ, 08830, US

(21) Appl. No.: 09/993,089

(22) Filed: Nov. 6, 2001

Related U.S. Application Data
(60) Provisional application No. 60/248,102, filed on Nov. 13, 2000.

(51) Int. Cl. H05K 7/20

(52) U.S. Cl. 361/704

(57) ABSTRACT

A medical workstation chassis including a first compartment and a second compartment. The first compartment is formed as a monolithic aluminum casting which includes pedestals which mate to heat generating electronic components such as integrated circuits mounted within the first compartment. A plastic thermal barrier is sandwiched between the first compartment and the second compartment to attenuate heat transfer from the chassis to the components, such as a disk drive and battery, housed within the second compartment. A series of heat sink fins are formed along the lateral perimeter of the aluminum casting and are interconnected to the pedestals by a series of large cross section ribs which are also formed as part of the aluminum casting.

### CROSS REFERENCE TO RELATED APPLICATIONS

This application is a nonprovisional application based on Provisional Applications Serial No. 60/248,102, filed on Nov. 13, 2000.

### FIELD OF THE INVENTION

The present invention relates generally to the mechanical housing for an electronic assembly, and more particularly to a computer housing which does not require the use of forced air cooling.

### BACKGROUND OF THE INVENTION

Some medical workstations are computer based devices that are often placed permanently near the patient's bedside. These devices are similar in computing capability and power usage to a laptop personal computer, containing a microprocessor and its associated components. Due to the medical environment, the use of a fan to keep the workstation cool is sometimes not possible, as for example in a burn ward. The absence of a fan is also advantageous insofar as noise is reduced and therefore does not interfere with patient sleep. Further, the absence of a fan eliminates the need for filter cleaning or replacement.

A typical microprocessor such as a Pentium III can dissipate as much as ten watts of heat energy. The microprocessor necessarily resides near other electronic components such as disk drives and batteries which need to be maintained near ambient room temperature. A fan is typically used to force air through the computer in order to maintain acceptable temperatures within a mechanically compact package.

For example, U.S. Pat. No. 6,130,818 entitled ELECTRONIC ASSEMBLY WITH FAULT TOLERANT COOLING, issued Oct. 10, 2000 to Severson discloses one such technique. The system disclosed in this patent includes a passive heat sink interconnected to an active heat sink. The active heat sink receives forced air from a fan and has sufficient capacity to keep the electronic components cool even if some of the vent passageways become clogged or blocked.

Another example of a cooling system for electronic components is disclosed in U.S. Pat. No. 5,892,654, entitled APPARATUS FOR IMPROVED AIR FLOW THROUGH A COMPUTER CHASSIS, issued on Apr. 6, 1999 to Worden, Jr. The '654 apparatus includes vent openings at the front and rear of the chassis. The circuit boards mounted within the chassis are aligned and spaced so as to serve as baffles for the airflow through the chassis.

A cooling system for medical equipment is disclosed in U.S. Pat. No. 5,485,349, entitled HEAT DISSIPATING ELECTRONIC APPARATUS FOR USE AT A PATIENT'S BEDSIDE, issued on Jan. 16, 1996 to Kelly et al. The Kelly device uses a central chimney extending upwardly through a blood pressure monitoring device to conduct heat generated during operation. While this arrangement is suitable for a chassis that is relatively slender, it does not provide sufficient heat dissipation for a heat generating mechanical package that is relatively short and flat.

A final example of computer cooling system is disclosed in U.S. Pat. No. 5,243,493, entitled FANLESS CONVECTION COOLING DESIGN FOR PERSONAL COMPUTERS, issued on Sep. 7, 1993 to Jeng et. al. The Jeng et al. device mounts the warmest components at the top of a large housing, using vertically oriented, internally mounted circuit boards to direct convective air flow from the bottom to the top of the cabinet. In order to gain access to the interior of the cabinet the top must be hinged, risking the introduction of debris and liquids into the cabinet. Further, in order to achieve the desired heat dissipating capacity the cabinet is a relatively large, substantially cubical structure.

### BRIEF SUMMARY OF THE INVENTION

In accordance with the principles of the present invention, a workstation chassis is provided which maintains a relatively low profile while maintaining a high heat dissipation capacity without the use of a fan. Further, the mechanical construction is such that the interior of the chassis is protected from outside contamination and particularly from the intrusion of liquids.

The chassis includes two compartments, the first being formed by an aluminum casting with integrally formed heat sink fins. The second compartment is formed to enclose the batteries and disk drives, and is mechanically coupled to but thermally isolated from the first compartment. Pedestals are used to interconnect the warmest internal components to ribs that reach the perimeter heat sink fins.

### BRIEF DESCRIPTION OF THE DRAWING

In the drawing:

FIG. 1 is a plan view of a chassis constructed according to the principles of the present invention;

FIG. 2 is a perspective view of the chassis depicted in FIG. 1;

FIG. 3 is an exploded perspective view of a workstation including the chassis depicted in FIG. 2; and

FIG. 4 is a perspective view of the assembled workstation depicted in FIG. 3.

### DETAILED DESCRIPTION OF THE INVENTION

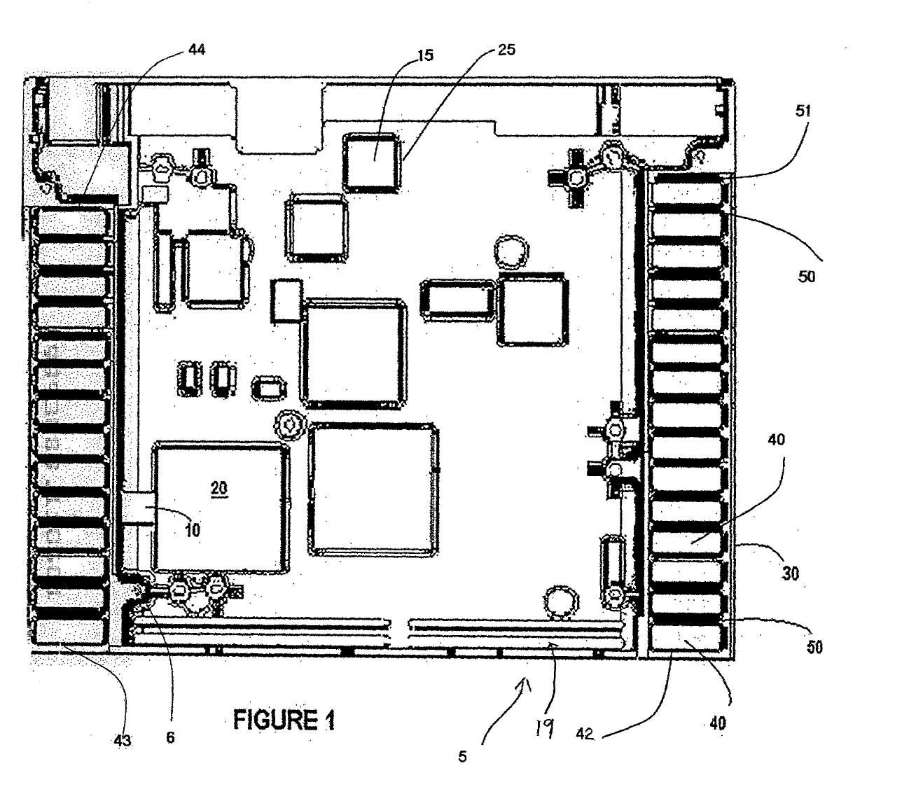

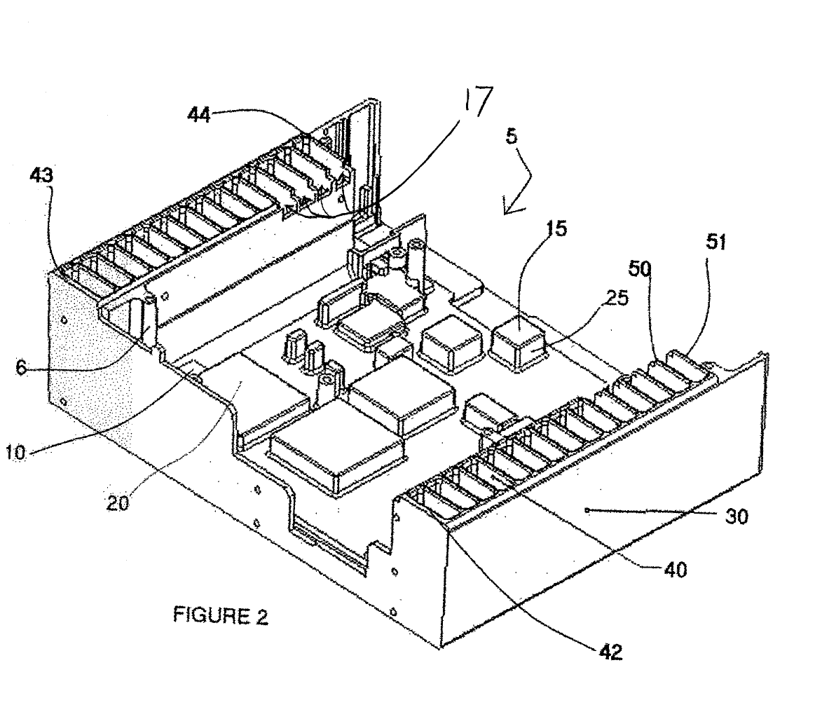

The following description relates to a particular medical workstation but this is not part of the invention. The drawings are not to scale, and many details have been omitted in the interest of clarity. FIG. 1 is a plan view and FIG. 2 is a perspective view of a chassis constructed according to the principles of the present invention. In FIG. 1 and FIG. 2, a medical workstation includes an aluminum casting 5 which includes integrally formed heatsink fins such as fins 42, 43,44, 50 and 51. The fins create between them a series of voids 40 which tend to thermally isolate adjacent fins and thereby assist in the dissipation of heat being radiated by the fins. The fins are formed to abut an external dress wall 30, which conceals the fins from external view while providing an enlarged surface area to increase the rate of heat dissipation.

Integrally formed as part of the casting are a series of pedestals such as pedestals 20 and 15. Each pedestal is dimensioned so as to mate to a particular heat generating component (not shown), such as a microprocessor or other integrated circuit. The pedestals have sidewalls 25 dimensioned to accommodate the electronic component (not shown) which abut the pedestal. The pedestals are linked to the fins 43, for example, by integrally formed ribs such as rib 10 in order to further assist with heat dissipation. Not every electronic component in the workstation generates a large amount of heat and so not every component is mated to a pedestal. Relatively low heat generating components are cooled by convection via air intakes 19 on the bottom of the casting 5 and exhaust vents such as vent 17. The path defined by the air intakes and exhaust vent 17 has continuous walls (not visible from outside of unit) which causes liquid spilled into void 40 to pass through the aluminum casting 5 without any opportunity to contact electronic components mounted thereon.

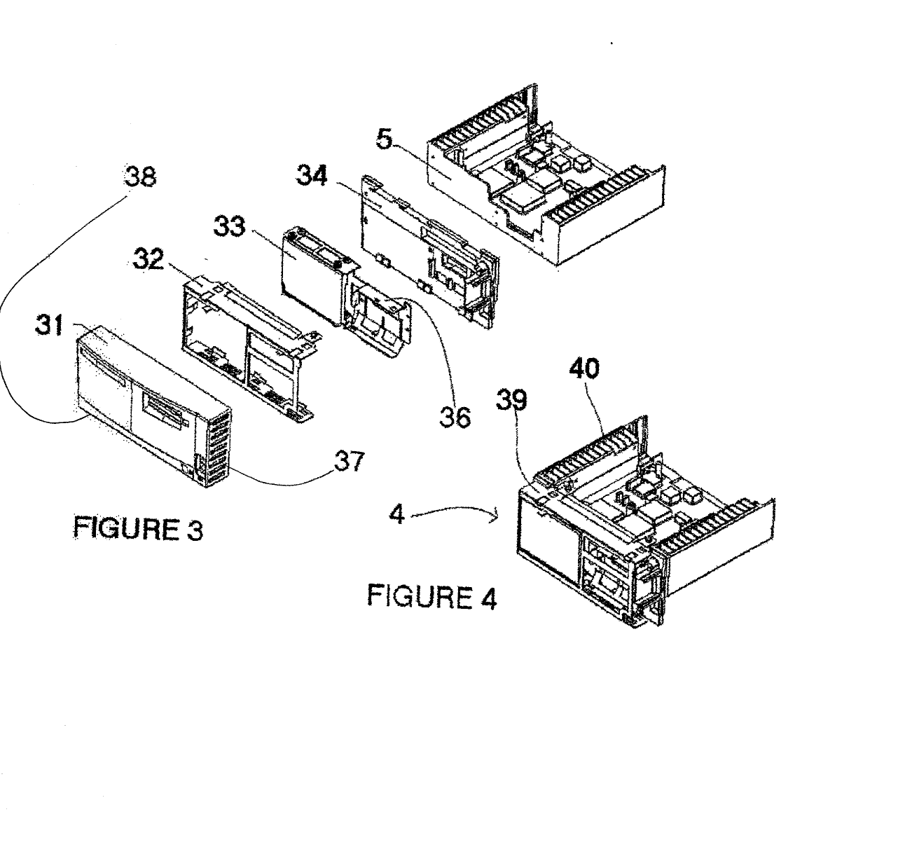

Referring now to FIG. 3 and FIG. 4, the assembled workstation 4 includes a second compartment 33 which houses other components such as a disk drive and batteries. The compartment 33 provides convection cooling for its internally housed components via intake bottom vents 38 and exhaust side vents 37. The compartment 33 is mounted via a steel bracket 36 to a plastic thermal barrier 34. The thermal barrier 34 is affixed to the aluminum chassis 5 and has sufficient depth to include several voids or air pockets which assist in providing thermal isolation between the casting 5 and the second compartment 33.

An electromagnetic interference shield 32 is affixed to the second compartment 33. A cover 31 (not present in FIG. 4) is affixed to the shield 32 in order to provide debris protection and to improve aesthetics. One requirement of a medical workstation is that it pass a liquid spill test for safety and reliability. This is accomplished by having no openings on the top 31 (FIG. 3 of the enclosure 4 except for the cooling fin voids 40. The voids 40 are isolated from the internal circuitry (not visible) and thus a liquid spill will not damage any active components. The cooling and thermal isolation properties of the enclosure 4 are illustrated in the following example.

### EXAMPLE

Test 22: Cover 31 in place, power consumption is 10 watts

Test 23: Same as test 22 except power consumption increased to 24 watts

| | Temp. | Temp. |
|---|---|---|
| Thermocouple Location | (Test 22) | (Test 23) |
| Microprocessor Pedestal 20 | 19.8 C. | 22.9 C. |
| Right Rear Fin 51 | 17.2 C. | 19.6 C. |
| Right Front Fin 42 | 17.4 C. | 19.9 C. |
| Disk Drive in Compartment 33 | 6.8 C. | 7.7 C. |
| Battery in Compartment 33 | 7.0 C. | 8.1 C. |
| Left Front Fin 43 | 17.7 C. | 20.5 C. |
| Left Rear Fin 44 | 17.3 C. | 20.0 C. |
| Cover 31 | 16.1 C. | 18.3 C. |
| Main Circuit Board | 18.9 C. | 21.6 C. |

The approximate temperature of the fins 42, 43, 44 and 51 in test 22 is 17.5 degrees C, while the battery and disk drive have a temperature of approximately 7.0 degrees C, or a difference of approximately 10 degrees C. In test 23, the battery and disk drive temperature increase by about one degree while fin temperatures increase by two degrees.

What is claimed is:

1. A passive thermal dissipation and isolation housing, comprising:
a monolithic chassis formed to thermally mate with at least some heat producing components housed within the housing; and
a compartment abutting the monolithic chassis, the compartment containing and thermally isolating selected components from heat generated within the monolithic chassis.

2. The passive thermal dissipation and isolation housing of claim 1, wherein the monolithic chassis further comprises:
an aluminum base; and
a plurality of pedestals, each pedestal being integrally formed with and extending from the aluminum base, each pedestal being dimensioned to mate with a particular heat producing component.

3. The passive thermal dissipation and isolation housing of claim 2, further comprising a plurality of heat dissipating fins, each fin being formed integrally with and extending from the aluminum base.

4. The passive thermal dissipation and isolation housing of claim 3, further comprising a plurality of ribs, each rib being integrally formed with and extending from the aluminum base, each rib extending from at least one pedestal to at least one heat dissipating fin.

5. The passive thermal dissipation and isolation housing of claim 4, further comprising at least one convection path defined by an inlet orifice formed within a lower portion of the aluminum base and an exhaust vent pipe formed within an upper portion of the aluminum base.

6. The passive thermal dissipation and isolation housing of claim 5 wherein heat dissipating fins are formed as a series of substantially rectangular columns having a void region residing between adjacent fins.

7. An electronic apparatus for use in a flame free, liquid containing environment, comprising:
a first compartment housing heat generating electronic components; and
a second compartment housing electronic components; and
a thermal barrier, the thermal barrier being affixed to and between the first and second compartments, thereby permitting the first compartment to be mounted adjacent to the second compartment while attenuating heat transfer from the first compartment to the second compartment.

8. The electronic apparatus of claim 7, wherein the thermal barrier comprises:
a substantially thermally nonconductive frame; and
at least one void region defined by the frame, the void region tending to further attenuate the transfer of heat from the first compartment to the second compartment.

9. The electronic apparatus of claim 8, wherein the first compartment comprises:
an aluminum casting;
a plurality of heat dissipating fins formed along perimeter regions of the casting; and
a plurality of pedestals integrally formed in the aluminum casting which abut heat generating electronic components mounted within the first compartment.

10. The electronic apparatus of claim 9, wherein the second compartment comprises:
a region for mounting heat sensitive components; and
a bracket for affixing the second compartment to the thermal barrier.
